(19) United States
(12) Patent Application Publication
(10) Pub. No.: US 2026/0180560 A1
(43) Pub. Date: Jun. 25, 2026

(54) CHARGE PUMP-BASED PULSE GENERATOR

(71) Applicants: Yuanming Zhu, Portland, OR (US); Susnata Mondal, Hillsboro, OR (US); Mozhgan Mansuri, Portland, OR (US)

(72) Inventors: Yuanming Zhu, Portland, OR (US); Susnata Mondal, Hillsboro, OR (US); Mozhgan Mansuri, Portland, OR (US)

(21) Appl. No.: 18/988,648

(22) Filed: Dec. 19, 2024

(51) Int. Cl. H03K 3/356

(52) U.S. Cl. CPC H03K 3/356113

(57) ABSTRACT

An apparatus includes a capacitor, a first plurality of transistors, a transmission gate, and a second plurality of transistors. The first plurality of transistors is coupled in series with each other via the capacitor. The first plurality of transistors are coupled between a first supply voltage terminal and a ground terminal. The transmission gate is coupled to a second supply voltage terminal. The second plurality of transistors are coupled to the transmission gate via the capacitor. The second plurality of transistors are coupled to a data input terminal and an output terminal.

### BACKGROUND

Continuous increase of system data traffic uses circuit techniques to aggressively scale supply and improve energy efficiency of various wireline links, such as Universal Chiplet Interconnect Express (UCIe) for die-to-die input-output (IO), off-package chip-to-chip IO through the bottom side or the top side of the package, Peripheral Component Interconnect Express (PCIe), electrical SerDes links, integrated/discrete optical links, high-bandwidth memory interfaces, etc. However, increases in system data traffic can lead to high power consumption.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings listed below.

FIG. 1 is a block diagram of a high-supply-voltage high-swing 1-unit interval (UI) pulse generator and low-voltage NMOS-over-NMOS (N/N) driver, in accordance with some embodiments.

FIG. 2 is a block diagram of a supply-scalable low-voltage transmit (Tx) circuit employing a charge-pump-based high-swing 1-UI pulse generator and N/N driver, in accordance with some embodiments.

FIG. 3 is a block diagram of a supply-scalable low-voltage Tx circuit employing a charge-pump-based high-swing 1-UI pulse generator, N/N driver, and a pre-driver stage, in accordance with some embodiments.

FIG. 4 is a block diagram of charge-pump-based 1-UI pulse generator, in accordance with some embodiments.

FIG. 5 is a timing diagram of input sub-rate data, clock, output, and various internal nodes for the pulse generator of FIG. 4, in accordance with some embodiments.

FIG. 6 is a diagram of simulated transient waveforms of the pulse generator of FIG. 4, in accordance with some embodiments.

FIG. 7 is a diagram of transient simulation with input pattern transit from long ‘0’ to long ‘1’ of the pulse generator of FIG. 4, in accordance with some embodiments.

FIG. 8 is a diagram of Tx simulations with 25-mm UCIe reference channel over standard package using a 1-UI pulse generator operating at 0.8V and low-voltage N/N driver at 0.5V, in accordance with some embodiments.

FIG. 9 is a diagram of Tx simulations with 25-mm UCIe reference channel over standard package using the pulse generator of FIG. 4, in accordance with some embodiments.

FIG. 10 is a diagram of a 4:1 MUX and driver merged architecture, in accordance with some embodiments.

FIG. 11 is a diagram of a 4:1 MUX and driver merged architecture using the disclosed pulse generator, in accordance with some embodiments.

FIG. 12 is a flow diagram of an example method for making a pulse generator circuit, in accordance with some embodiments.

FIG. 13 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

As used herein, the term “IO” indicates input/output. As used herein, the term “R-C” indicates resistance and capacitance. As used herein, the term “Rx” indicates receiver (or receive). As used herein, the term “Tx” indicates transmitter (or transmit). As used herein, the term “TRX” indicates transceiver. As used herein, the term “UCIe” indicates Universal Chiplet Interconnect Express. As used herein, the term “Vref” indicates reference voltage. As used herein, the term “Vin” indicates input voltage. As used herein, the terms “serially coupled,” “serially connected,” and “connected in series” are synonymous to each other and indicate a serial connection between two or more components/circuits where the serial connection can be based on a direct or indirect electrical connection between the two or more components/circuits. As used herein, the terms “parallel coupled,” “parallel connected,” and “connected in parallel” are synonymous to each other and indicate a parallel connection between two or more components/circuits where the parallel connection can be based on a direct or indirect electrical connection between the two or more components/circuits.

In the Tx side of the electrical link, low-power voltage-mode electrical transmitters can use high swing 1-UI pulse generation to achieve good eye height, better driver bandwidth (BW), and better driver linearity. This processing can be associated with higher-supply-voltage operation of the 1-UI pulse generator and preceding stages, demanding higher power consumption. The disclosed techniques include a change-pump-based 1-UI pulse generator that can generate a high-swing 1-UI pulse even when operating from a lower supply voltage, simultaneously improving eye margins, driver linearity, and energy efficiency.

Some solutions include a Tx architecture using high-supply-voltage 1-UI pulse generator and low-supply-voltage voltage-mode driver, and supply-scalable Tx using 1-UI pulse generator and voltage-mode driver, both running at low supply voltage. However, high-supply-voltage 1-UI pulse generator and low-supply-voltage voltage-mode driver requires two separate power supplies and achieves poor energy efficiency due to high-supply-voltage operation of the 1-UI pulse generation and all preceding stages. Additionally, a supply-scalable TX architecture using a conventional 1-UI pulse generator running at a low supply voltage has poor BW of the 1-UI pulse generation stage, driver non-linearity, and poor energy efficiency from the up-sizing of the drive, 1-UI pulse gen, and preceding sub-rate stages.

The disclosed techniques include a high-speed, supply-scalable, energy-efficient wireline Tx architecture that introduces a high-swing yet low-power charge-pump-based 1-UI pulse generator combined with a low-power voltage-mode NMOS-over-NMOS driver. The proposed charge-pump-based 1-UI generator boosts the output pulse amplitude by approximately two times, enabling low-supply-voltage operation of the entire high-speed TX without up-sizing the driver stage (and all preceding stages), improving energy efficiency and output bandwidth. In an example design of 32 GT/s UCIe did-to-die link over a standard package, the proposed Tx architecture achieves 1.25 times better eye height and 1.6 times better energy efficiency than conventional 1-UI pulse generator-based TX when running at a scaled supply.

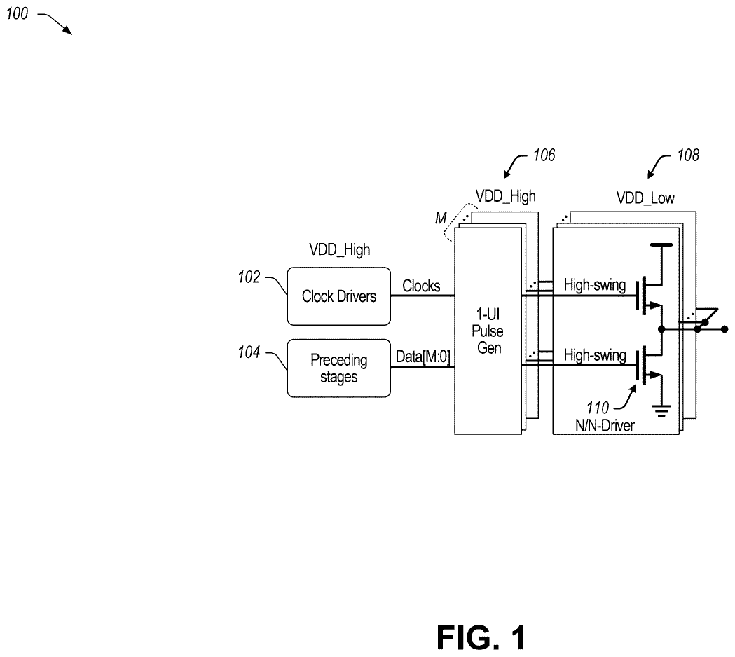

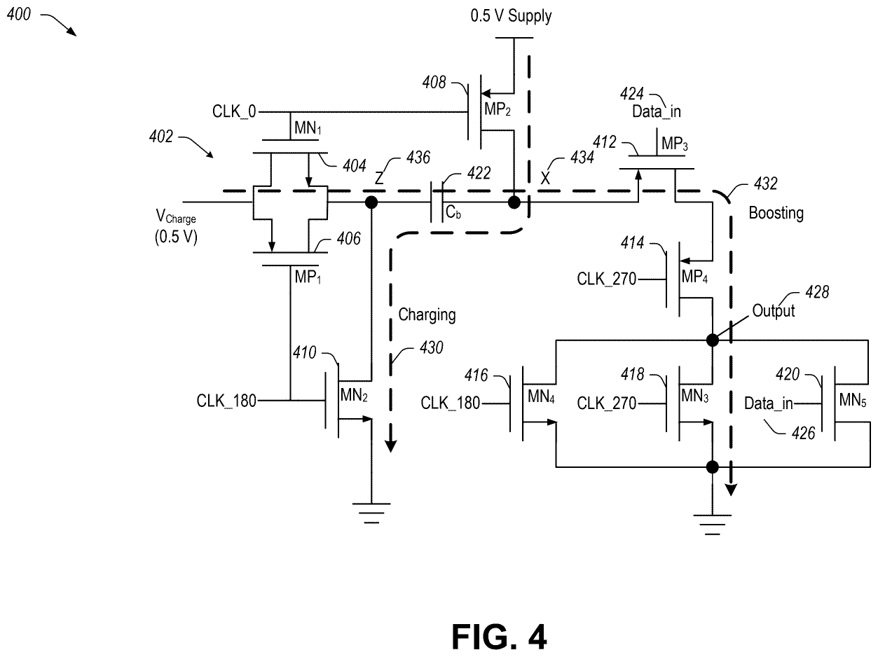

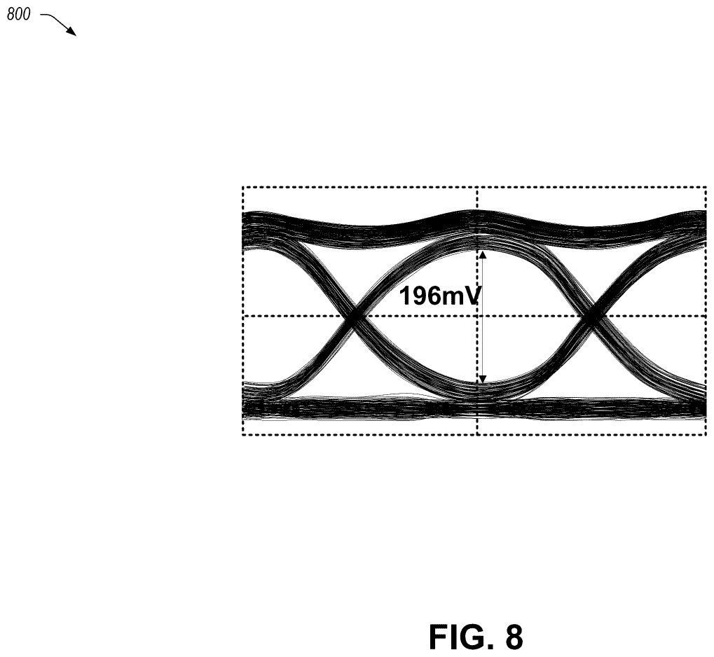

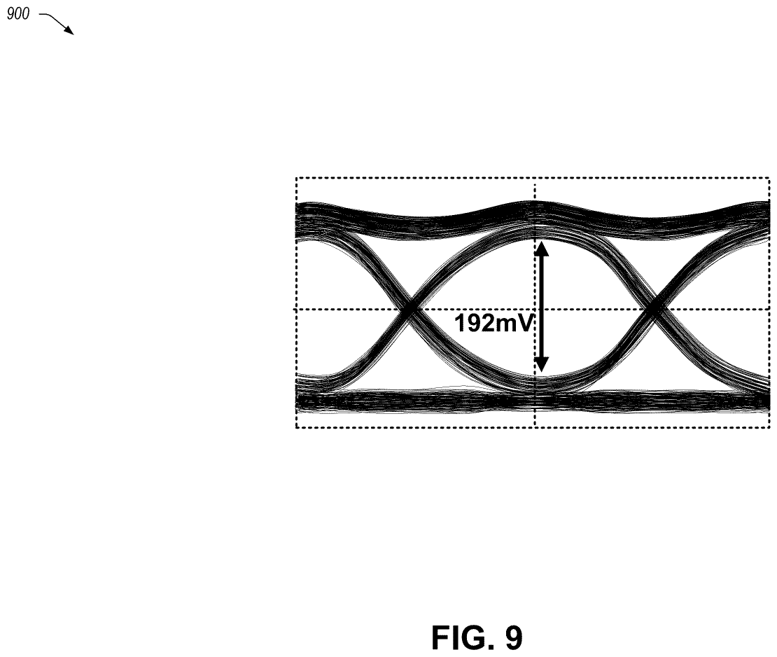

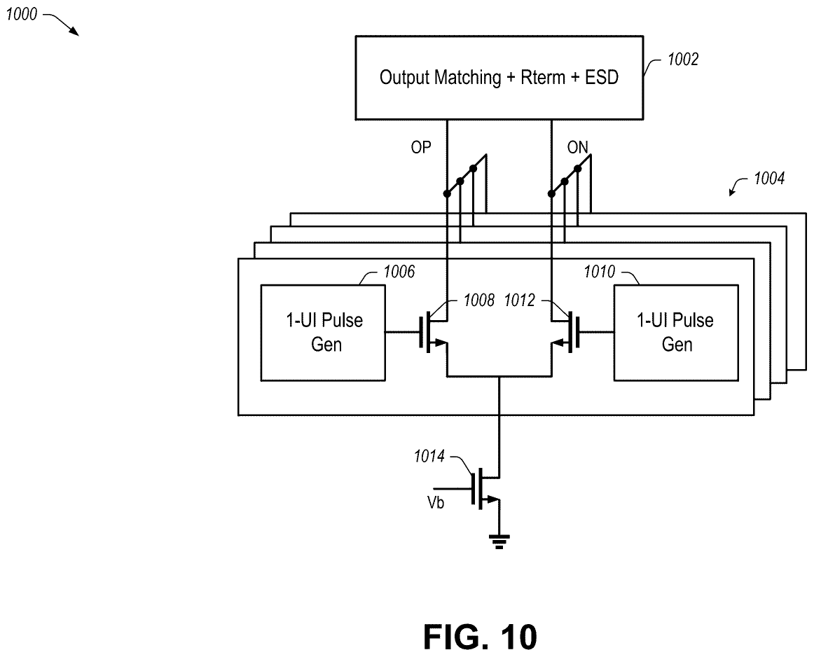

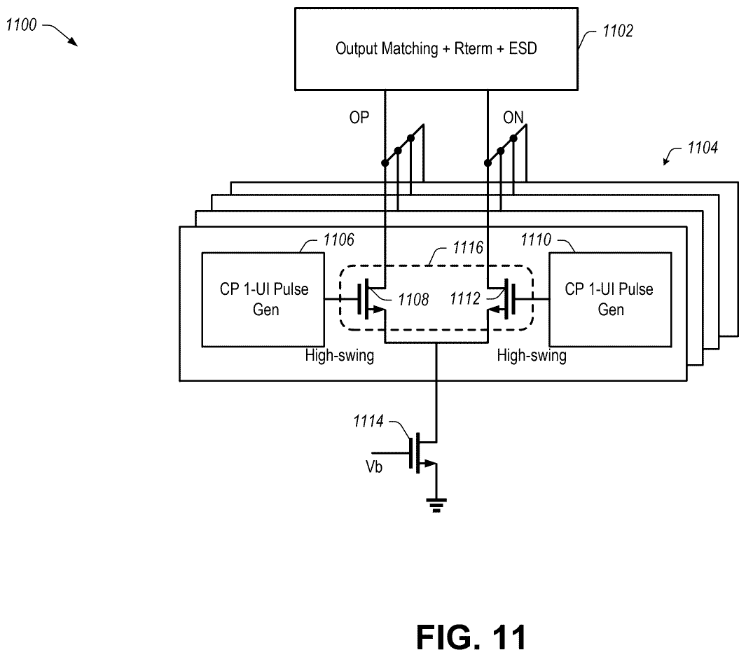

The disclosed techniques include a charge-pump-based 1-UI pulse generator for low-power wireline Txs. It is described below in four parts. First, a supply-scalable electrical Tx architecture is disclosed that includes a pulse-amplitude-boosted 1-UI pulse generator to improve the overall energy efficiency of the pulse generator stage, the preceding clock/data paths, and the succeeding combiner/driver stages (e.g., FIGS. 1-3). Second, the circuit architecture of a 1-UI pulse generator employing charge-pump-based pulse amplitude boosting is introduced (e.g., FIGS. 4-7). Third, full Tx system simulations are presented including charge-pump-based 1-UI pulse generator and voltage-mode low-swing NMOS-over-NMOS driver, showcasing greater than 1.5 times energy-efficiency improvement over prior-art for an example UCIe 32 GT/s design (e.g., FIGS. 8-9). Finally, it is shown how the proposed change-pump-based 1-UI pulse generator can also be applied to improve energy efficiency of other wireline-TX/SERDES architectures (e.g., FIGS. 10-11).

FIG. 1 is a block diagram of a high-supply-voltage high-swing 1-unit interval (UI) pulse generator and low-voltage NMOS-over-NMOS (N/N) driver, in accordance with some embodiments. Referring to FIG. 1, circuit 100 includes clock drivers 102 (powered by Vdd_high), preceding stages 104, one or more pulse generators 106 (powered by Vdd_high), and one or more N/N drivers 108 (powered by Vdd_low, with each driver including a plurality of transistors 110).

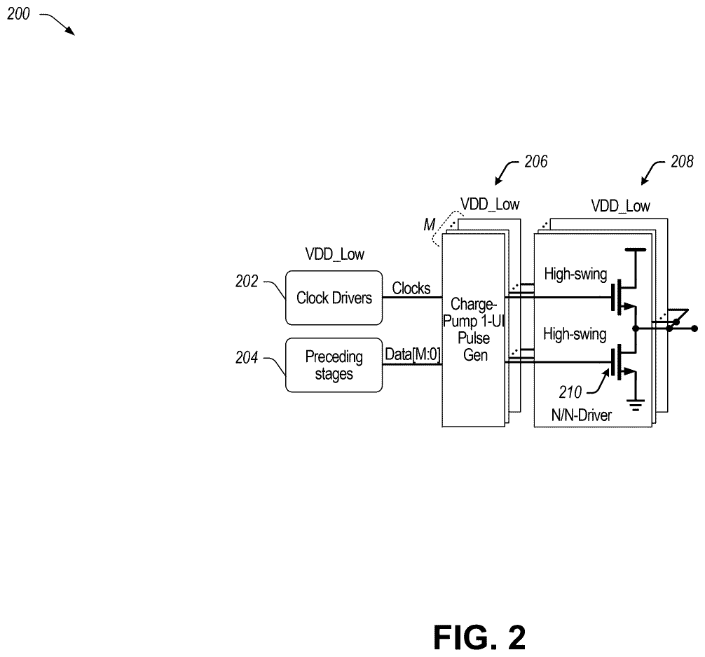

FIG. 2 is a block diagram of a supply-scalable low-voltage transmit (Tx) circuit employing a charge-pump-based high-swing 1-UI pulse generator and N/N driver, in accordance with some embodiments. Referring to FIG. 2, circuit 200 includes clock drivers 202 (powered by Vdd_low), preceding stages 204, one or more pulse generators 206 (powered by Vdd_low), and one or more N/N drivers 208 (powered by Vdd_low, with each driver including a plurality of transistors 210).

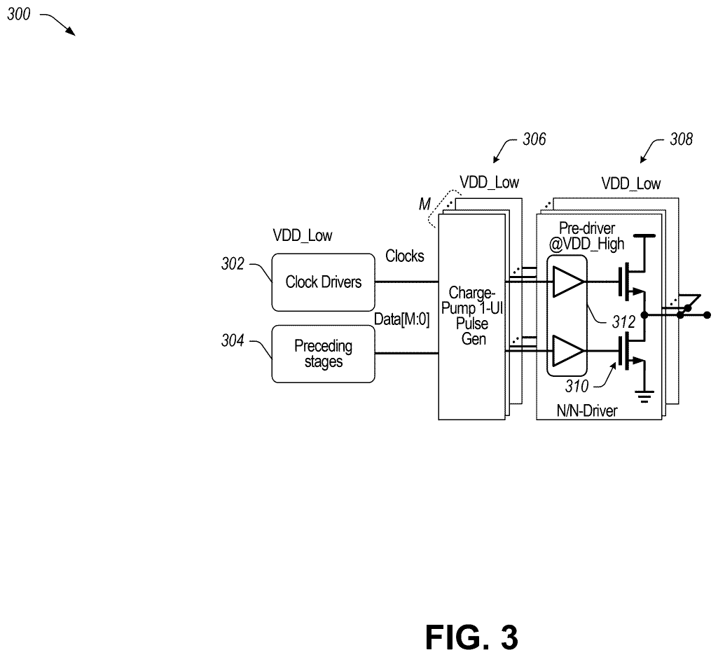

FIG. 3 is a block diagram of a supply-scalable low-voltage Tx circuit employing a charge-pump-based high-swing 1-UI pulse generator, N/N driver, and a pre-driver stage, in accordance with some embodiments. Referring to FIG. 3, circuit 300 includes clock drivers 302 (powered by Vdd_low), preceding stages 304, one or more pulse generators 306 (powered by Vdd_low), and one or more N/N drivers 308 (powered by Vdd_low). Each of the one or more N/N drivers 308 can include a plurality of transistors 310 and at least one pre-driver stage 312 (which can be powered by Vdd_high).

FIG. 1 shows a combined M:1 MUX and driver architecture suitable for energy-efficient wireline transmitters. In this architecture, from the sub-rate data and clock, each (of the M) 1-UI pulse generation stage generates a pulse with a pulse width of 1-UI of the full-rate data and stays low for the rest of the M-1 UI. 1-UI pulses from M such slices can then be combined using an explicit combiner stage (followed by the driver) or directly combined using the driver stage itself. It can be shown that directly combining at the driver is often beneficial as the driver output node is a low impedance node (due to output matching requirement) that helps to tolerate the higher capacitance of the embedded combiner. Moreover, direct combining at the driver output reduces the number of full-swing nodes in the system, thereby further improving energy efficiency. A low-swing NMOS-over-NMOS (N/N) driver can be used to improve the driver stage power consumption. Therefore, the architecture in FIG. 1 has low driver-stage power consumption from a low-supply-voltage N/N design and a relatively high combining-node bandwidth (BW) at the driver output. However, the 1-UI pulse generator and all preceding stages in this architecture operate at a higher supply voltage to ensure deep-triode operation of the N/N driver and, hence, output impedance linearity. Therefore, this architecture requires two supply domains with higher power consumption in the 1-UI pulse generator and all preceding stages that run from the higher supply domain.

In order to improve energy efficiency, a supply scalable architecture needs to be explored. However, suppose the supply of the conventional 1-UI pulse generation stage and all preceding stages in FIG. 1 is reduced. In that case, the N/N driver needs to be significantly upsized to achieve similar driving capability and output impedance, increasing driver power and reducing output node bandwidth. Moreover, the driver upsizing necessitates the upsizing of the 1-UI pulse generation stage that drives the N/N and any preceding sub-rate data and clocking stages, further degrading energy efficiency. Furthermore, low-swing pulses at the N/N input restrain N/N devices from going to deep-trade, increasing driver output impedance variation and degrading driver linearity. Another drawback would be the native lower bandwidth of the 1-UI pulse generation stage itself due to low-supply operation.

To overcome the supply scalability challenges of the architecture in FIG. 1, the disclosed techniques include an amplitude-boosted 1-UI pulse generation where the pulse amplitude can be boosted to roughly two times the pulse generator supply. Due to the availability of high-swing pulses from a low-supply 1-UI pulse generator, the proposed architecture in FIG. 2 has the following advantages:
(a) All Tx blocks, including the driver, 1-UI pulse generator, and all preceding stages, can run from a single low-supply voltage.
(b) The driver stage does not need to be upsized with regard to the same circuit in FIG. 1, improving driver power and output node bandwidth (BW).
(c) The 1-UI pulse generation stage that drives the driver also does not need to be upsized, improving energy efficiency.
(d) By boosting the output amplitude from a low supply stage, the proposed 1-UI pulse generator can have a higher native BW.
(e) No upsizing is required for all sub-rate stages, improving energy efficiency.
(f) The output driver in the proposed technique exhibits low output impedance variation and superior linearity, similar to FIG. 1.

In order to further improve the energy efficiency of the proposed Tx in FIG. 2, pre-driver stages (e.g., at least one pre-driver stage 312) are inserted between the pulse generator and the driver (see FIG. 3) that run from a higher supply domain. These additional pre-driver stages help downsize the 1-UI pulse generator, significantly improving pulse-gen power consumption and overall energy efficiency.

FIG. 4 is a block diagram of a charge-pump-based 1-UI pulse generator, in accordance with some embodiments.

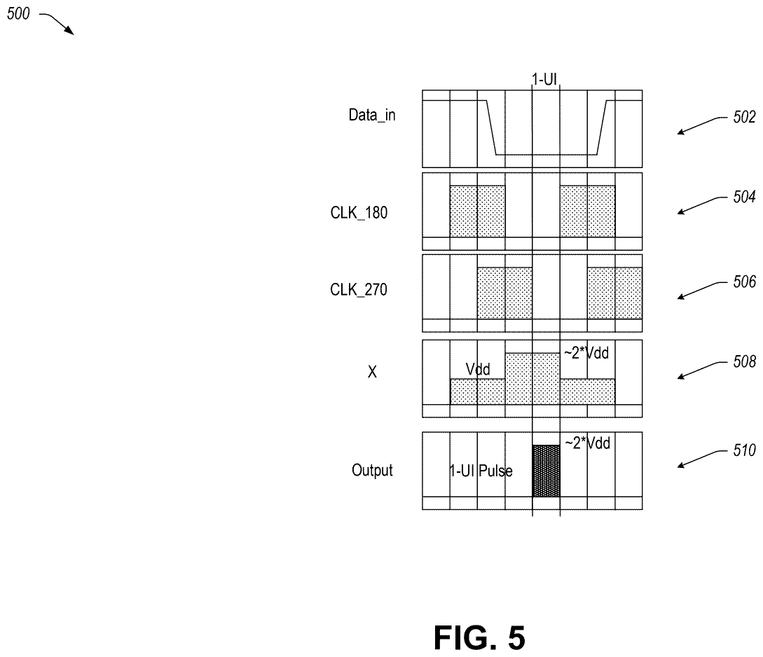

FIG. 5 is a timing diagram 500 of input sub-rate data 502, clock signals 504 and 506, output 510, and various internal nodes (e.g., node X 508) for the pulse generator of FIG. 4, in accordance with some embodiments.

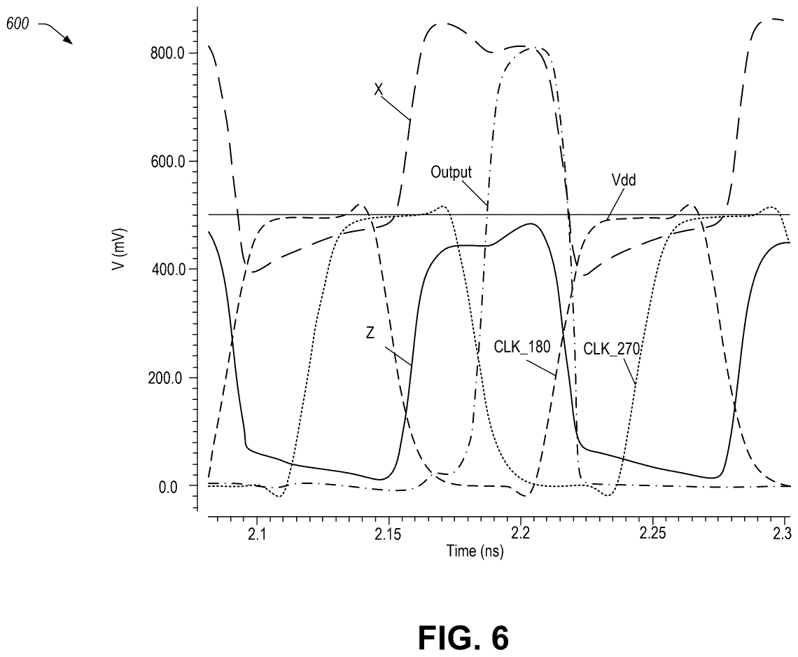

FIG. 6 is a diagram 600 of simulated transient waveforms of the pulse generator of FIG. 4, in accordance with some embodiments.

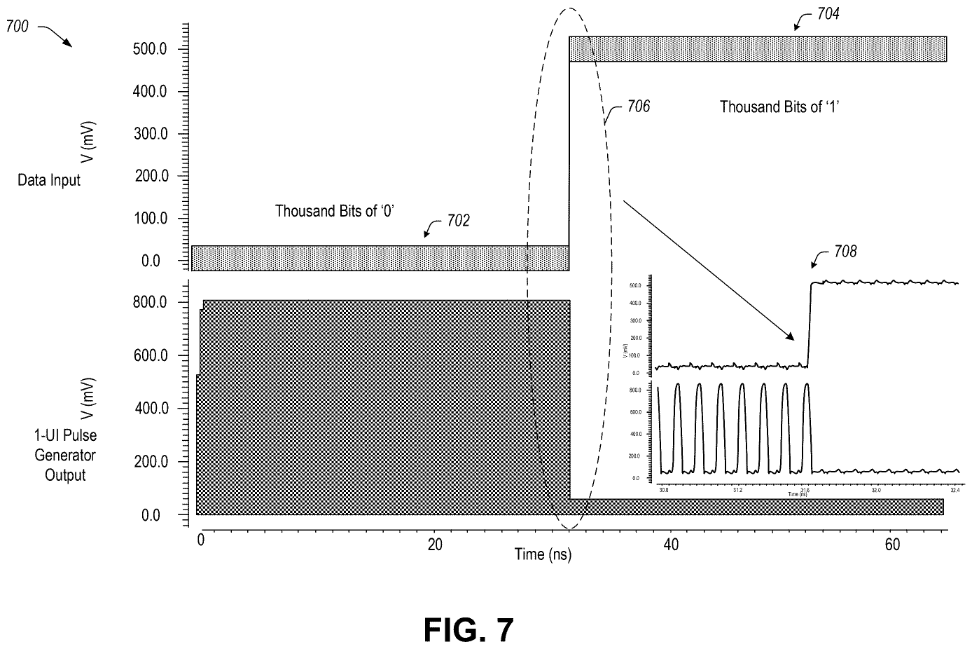

FIG. 7 is a diagram 700 of transient simulation with input pattern transit from long ‘0’ (e.g., data pattern 702) to long ‘1’ (e.g., data pattern 704) of the pulse generator of FIG. 4, in accordance with some embodiments. Diagram 700 also illustrates a magnified graph 708 of graph portion 706 of input data and pulse generator output graphs.

Referring to FIG. 4, pulse generator 400 includes Tx gate 402 (which includes transistors 404 and 406, also indicated as MN1 and MP1, respectively), transistor 408 (also referenced as MP2), transistor 410 (also referenced as MN2), transistor 412 (also referenced as MP3), transistor 414 (also referenced as MP4), transistor 416 (also referenced as MN4), transistor 418 (also referenced as MN3), transistor 420 (also referenced as MN5), and capacitor 422. Transistors MP4, MN4, MN3, and MN5 are coupled to form an output terminal 428 (as illustrated in FIG. 4).

In some aspects, input data signals 424 and 426 are supplied to the gates of transistors MP3 and MN5, respectively.

In some aspects, a first supply voltage (or voltage signal) is provided to transistor MP2, and a second supply voltage (or charge voltage) is provided to Tx gate 402.

In some aspects, phase-shifted clock signals CLK_0, CLK_180, and CLK_270 are provided as gate signals, as illustrated in FIG. 4.

In some aspects, to achieve pulse-amplitude-boosting, pulse generator 400 primarily operates in two phases: the charging phase (associated with charging path 430) and the boosting phase (associated with boosting path 432). Although the proposed architecture can be generalized to any N-way multiplexing (or MUXing) operation, the working principle for N=4 is explained below in reference to FIGS. 5-7.

During the charging phase, when CLK_180 is high (hence, CLK_0 is low), capacitor 422 (also referenced as Cb) is charged to Vdd_low through MP2 and MN2 transistors. In this phase, one terminal of the capacitor is at the potential of Vdd_low, and the other terminal is at Vss.

In the boosting phase, when CLK_180 is low (hence, CLK_0 is high), node Z 436 is connected to Vcharge by MN1 and MP1 transistors. In this phase, as the supply drive to node X 434 through MP2 also cuts off, the instantaneous change in the capacitor Cb roughly stays constant, and the X node potential is boosted to Vcharge+Vdd_low (0.5V supply voltage). In the simulation, Vcharge is assumed to be the same as Vdd_low for simplicity. In some aspects, Vcharge is generated from Vdd_low and is programmable, enabling the circuit to adapt to different supply voltages while avoiding excessive voltage stress (EOS). Next, the CLK_270 clock signal, which is at 1-UI delay with regard to CLK_180, goes to zero, transferring the change from node X to the output node through MP4. Finally, after 1-UI more delay, when CLK_180 again goes high, X node is discharged via MN4, and a boosted 1-UI pulse is generated at the output. Since each 1-UI pulse generator operates with 4 UI periods, the pulse generator completes a full cycle of charging, boosting, and discharging for each bit, meaning there is no limitation related to the density of the data pattern.

FIG. 7 shows the transient simulation, illustrating the transition of the input pattern from a long sequence of ‘0’s to a long sequence of ‘1’s. The 1-UI pulse generator output immediately transitions to low (‘0’) when the data input switches to high (‘1’). In some aspects, the maximum output swing is limited by the maximum supply voltage of the specific process used.

FIG. 8 is a diagram 800 of Tx simulations with a 25-mm UCIe reference channel over a standard package using a 1-UI pulse generator operating at 0.8V and low-voltage N/N driver at 0.5V, in accordance with some embodiments.

FIG. 9 is a diagram 900 of Tx simulations with a 25-mm UCIe reference channel over a standard package using the pulse generator of FIG. 4, in accordance with some embodiments.

The eye diagrams 800 and 900 are plotted at a 50 Ω termination resistor at the receiver (Rx) input after the channel. The architecture in FIG. 1 with a 1-UI pulse generator (and all preceding stages) operating at 0.8V and low-voltage N/N driver at 0.5V achieves a good eye height of 196 mV (e.g., FIG. 8). However, as all blocks except the N/N are powered from a higher supply, this architecture achieves poor Tx energy efficiency of 211 fJ/b.

The architecture in FIG. 2 is simulated, including the proposed charge-pump-based 1-UI pulse generator in FIG. 4, where all blocks use a single low 0.5V supply. It can be seen in FIG. 9 that as high-swing pulses are available at the input of the N/N, the proposed architecture achieves 192 mV of eye height without requiring any driver up-scaling, thanks to the amplitude-boosted charge-pump-based 1-UI generator. Moreover, in this architecture, as all stages operate from the same low supply and do not require up-scaled sizes, a high energy efficiency of 140 fJ/b is achieved, which is more than 1.5 times better than existing technologies. Moreover, after adding the pre-driver stages shown in FIG. 3, the overall power consumption is further reduced by 20% (achieved energy efficiency is 112 fJ/b) while maintaining the same eye-opening.

FIG. 10 is a diagram of a 4:1 MUX and driver-merged architecture, in accordance with some embodiments. Referring to FIG. 10, architecture 1000 includes an output matching circuit 1002 and signal processing slices 1004 coupled to ground via transistor 1014. An example slice of the signal processing slices 1004 includes pulse generators 1006 and 1010 coupled to transistor 1014 via corresponding transistors 1008 and 1012.

FIG. 11 is a diagram of a 4:1 MUX and driver-merged architecture using the disclosed pulse generator, in accordance with some embodiments. Referring to FIG. 11, architecture 1100 includes an output matching circuit 1102 and signal processing slices 1104 coupled to ground via transistor 1114. An example slice of the signal processing slices 1104 includes pulse generators 1106 and 1110 (which can be configured based on the disclosed techniques) coupled to transistor 1114 and the output matching circuit 1102 via corresponding transistors 1108 and 1112 forming an output driver 1116.

In some aspects, an architecture can use the CML 4:1 MUX directly as a driver, as shown in FIG. 10. This architecture also removes internal full-rate nets except for the output pad, where passive inductors are used to extend the bandwidth. This approach can be power/area-efficient; however, it can introduce large output loading capacitance from the 4-way interleaved driver, posing a challenge for ultra-high-speed design.

The disclosed techniques can be applied to alleviate power and speed tradeoffs in this design. FIG. 11 shows the improved architecture, where the proposed charge-pump 1-UI pulse generator can increase the input swing of the CML driver by roughly 2 times. This can significantly reduce the size of the output driver 1116 and the output capacitance while also avoiding the use of any high-power pre-driver, resulting in a high-speed and low-power design.

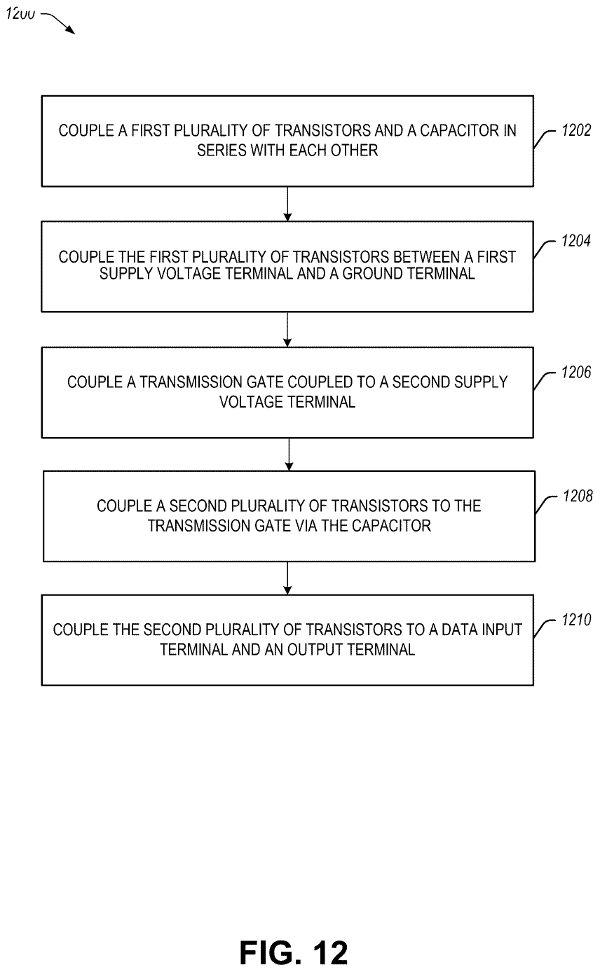

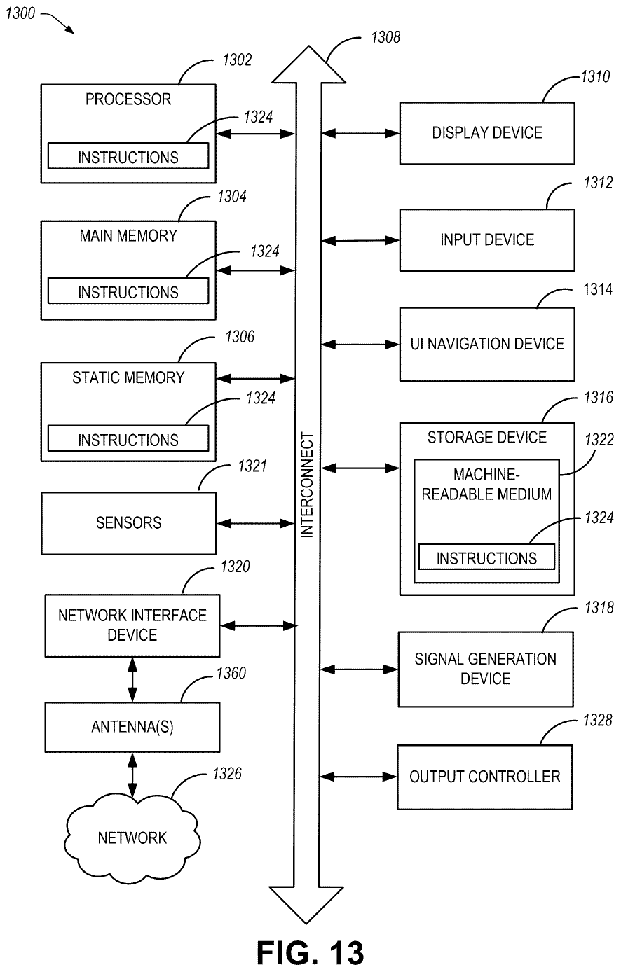

FIG. 12 is a flow diagram of an example method 1200 for making a pulse generator circuit, in accordance with some embodiments. Referring to FIG. 12, method 1200 includes operations 1202, 1204, 1206, 1208, and 1210, which may be executed by a processor, an embedded controller, a receiver circuit, a transceiver circuit, or another processor of a computing device (e.g., hardware processor 1302 of machine 1300 illustrated in FIG. 13, which can include one or more of the circuits discussed in connection with FIGS. 1-11). In some embodiments, one or more of the circuits discussed in connection with FIGS. 1-11 can perform the functionalities (or include the configurations or circuitry) associated with FIG. 12, as well as one or more of the examples listed below.

At operation 1202 and with reference to FIG. 4, a first plurality of transistors (e.g., MP2 and MN2) and a capacitor (e.g., capacitor 422) are coupled in series with each other;

At operation 1204, the first plurality of transistors (e.g., MP2 and MN2) are coupled between a first supply voltage terminal (e.g., 0.5V supply) and a ground terminal (e.g., ground terminal coupled to transistor MN2).

At operation 1206, a transmission gate (e.g., Tx gate 402) is coupled to a second supply voltage terminal (e.g., Vcharge).

At operation 1208, a second plurality of transistors (e.g., transistors MP3-MP4 and MN3-MN5) are coupled to the transmission gate via the capacitor.

At operation 1210, the second plurality of transistors to a data input terminal (e.g., data input terminals at transistors MP3 and MN5) and an output terminal (e.g., output terminal 428).

FIG. 13 illustrates a block diagram of an example machine 1300 upon which any one or more of the techniques (e.g., methodologies) discussed herein may perform. In alternative embodiments, the machine 1300 may operate as a standalone device or may be connected (e.g., networked) to other machines. In a networked deployment, machine 1300 may operate in the capacity of a server machine, a client machine, or both in server-client network environments. In an example, machine 1300 may function as a peer machine in a peer-to-peer (P2P) (or other distributed) network environment. The machine 1300 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 1300 may include a hardware processor 1302 (e.g., a central processing unit (CPU), a graphics processing unit (GPU), a hardware processor core, or any combination thereof), a main memory 1304, and a static memory 1306, some or all of which may communicate with each other via an interlink (e.g., bus) 1308. In some aspects, the main memory 1304, the static memory 1306, or any other type of memory (including cache memory) used by machine 1300 can be configured based on the disclosed techniques or can implement the disclosed memory devices.

Specific examples of main memory 1304 include Random Access Memory (RAM) and semiconductor memory devices, which may include, in some embodiments, storage locations in semiconductors such as registers. Specific examples of static memory 1306 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1300 may further include a display device 1310, an input device 1312 (e.g., a keyboard), and a user interface (UI) navigation device 1314 (e.g., a mouse). In an example, the display device 1310, the input device 1312, and the UI navigation device 1314 may be a touchscreen display. The machine 1300 may additionally include a storage device (e.g., drive unit or another mass storage device) 1316, a signal generation device 1318 (e.g., a speaker), a network interface device 1320, and one or more sensors 1321, such as a global positioning system (GPS) sensor, compass, accelerometer, or other sensors. The machine 1300 may include an output controller 1328, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 1302 and/or instructions 1324 may comprise processing circuitry and/or transceiver circuitry.

The storage device 1316 may include a machine-readable medium 1322 on which one or more sets of data structures or instructions 1324 (e.g., software) embodying or utilized by any one or more of the techniques or functions described herein can be stored. Instructions 1324 may also reside, completely or at least partially, within the main memory 1304, within static memory 1306, or the hardware processor 1302 during execution thereof by machine 1300. In an example, one or any combination of the hardware processor 1302, the main memory 1304, the static memory 1306, or the storage device 1316 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1322 is illustrated as a single medium, the term “machine-readable medium” may include a single medium or multiple media (e.g., a centralized or distributed database and/or associated caches and servers) configured to store instructions 1324.

An apparatus of machine 1300 may be one or more of a hardware processor 1302 (e.g., a central processing unit (CPU), a graphics processing unit (GPU), a hardware processor core, or any combination thereof), a main memory 1304 and a static memory 1306, one or more sensors 1321, a network interface device 1320, one or more antennas 1360, a display device 1310, an input device 1312, a UI navigation device 1314, a storage device 1316, instructions 1324, a signal generation device 1318, and an output controller 1328. The apparatus may be configured to perform one or more of the methods and/or operations disclosed herein. The apparatus may be intended as a component of machine 1300 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1300 and that causes machine 1300 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1324 may further be transmitted or received over a communications network 1326 using a transmission medium via the network interface device 1320 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.8.4 family of standards, a Long Term Evolution (LTE) family of standards, a Universal Mobile Telecommunications System (UMTS) family of standards, peer-to-peer (P2P) networks, among others.

In an example, the network interface device 1320 may include one or more physical jacks (e.g., Ethernet, coaxial, or phone jacks) or one or more antennas to connect to the communications network 1326. In an example, the network interface device 1320 may include one or more antennas 1360 to wirelessly communicate using at least one single-input multiple-output (SIMO), multiple-input multiple-output (MIMO), or multiple-input single-output (MISO) techniques. In some examples, the network interface device 1320 may wirelessly communicate using multiple-user MIMO techniques. The term “transmission medium” shall be taken to include any intangible medium that can store, encode, or carry instructions for execution by machine 1300 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, examples that include the elements shown or described are also contemplated. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is an apparatus comprising a first NMOS transistor comprising a gate terminal coupled to a first clock signal, a first PMOS transistor comprising a gate terminal coupled to a second clock signal, and a drain terminal of the first NMOS transistor coupled to a source terminal of the first PMOS transistor; a second NMOS transistor comprising a gate terminal coupled to the second clock signal and the gate terminal of the first PMOS transistor; and a second PMOS transistor comprising a gate terminal coupled to the gate terminal of the first NMOS transistor.

In Example 2, the subject matter of Example 1 includes a capacitor comprising a first terminal and a second terminal, the first terminal coupled to a source terminal of the first NMOS transistor, and a drain terminal of the first PMOS transistor.

In Example 3, the subject matter of Example 2 includes subject matter where the first terminal of the capacitor is further coupled to a drain terminal of the second NMOS transistor.

In Example 4, the subject matter of Examples 2-3 includes subject matter where the second terminal of the capacitor is coupled to a drain terminal of the second PMOS transistor.

In Example 5, the subject matter of Examples 2-4 includes a third PMOS transistor comprising a gate terminal coupled to an input data signal and a source terminal coupled to the second terminal of the capacitor.

In Example 6, the subject matter of Example 5 includes a fourth PMOS transistor comprising a source terminal coupled to a drain terminal of the third PMOS transistor and a drain terminal coupled to an output terminal of the pulse generator circuit.

In Example 7, the subject matter of Example 6 includes subject matter where the fourth PMOS transistor comprises a gate terminal coupled to a third clock signal.

In Example 8, the subject matter of Examples 6-7 includes a third NMOS transistor comprising a drain terminal coupled to the output terminal and a source terminal coupled to a ground terminal.

In Example 9, the subject matter of Example 8 includes subject matter where the third NMOS transistor comprises a gate terminal coupled to a third clock signal.

In Example 10, the subject matter of Example 9 includes, a fourth NMOS transistor comprising a drain terminal coupled to the output terminal, a source terminal coupled to the ground terminal, and a gate terminal coupled to the second clock signal.

In Example 11, the subject matter of Example 10 includes a fifth NMOS transistor comprising a drain terminal coupled to the output terminal, a source terminal coupled to the ground terminal, and a gate terminal coupled to the input data signal.

In Example 12, the subject matter of Examples 8-11 includes subject matter where the source terminal of the second PMOS transistor is coupled to a first voltage signal generated from a voltage source.

In Example 13, the subject matter of Example 12 includes subject matter where the drain terminal of the first NMOS transistor and the source terminal of the first PMOS transistor are coupled to a second voltage signal and wherein the second voltage signal is the same as the first voltage signal or is generated from the voltage source.

In Example 14, the subject matter of Examples 11-13 includes subject matter where the apparatus comprises a system-on-chip (SoC), the SoC comprising an integrated circuit (IC), the IC comprising at least two transistors of the first PMOS transistor, the second PMOS transistor, the third PMOS transistor, the fourth PMOS transistor, the first NMOS transistor, the second NMOS transistor, the third NMOS transistor, the fourth NMOS transistor, and the fifth NMOS transistor.

In Example 15, the subject matter of Example 14 includes subject matter where the SoC further comprises at least one connector and wherein the at least one connector conforms with at least one of Universal Serial Bus (USB), High-Definition Multimedia Interface (HDMI), Thunderbolt, Peripheral Component Interconnect Express (PCIe), Universal Chiplet Interconnect Express (UCIe), high-speed Double Data Rate (DDR) memory interface, and Ethernet specifications.

Example 16 is an apparatus comprising a capacitor; a first plurality of transistors coupled in series with each other via the capacitor, and the first plurality of transistors coupled between a first supply voltage terminal and a ground terminal, a transmission gate coupled to a second supply voltage terminal; and a second plurality of transistors coupled to the transmission gate via the capacitor, the second plurality of transistors coupled to a data input terminal and an output terminal.

In Example 17, the subject matter of Example 16 includes subject matter where the first plurality of transistors and the capacitor form a charging path, the charging path to charge the capacitor to a first pre-configured charge based on a first supply voltage at the first supply voltage terminal and a first set of phase-shifted clock signals coupled to corresponding gates of the first plurality of transistors.

In Example 18, the subject matter of Example 17 includes subject matter where the transmission gate, the capacitor, and the second plurality of transistors form a boosting path, the boosting path to boost the first pre-configured charge of the capacitor to a second pre-configured charge based on a second supply voltage at the second supply voltage terminal and a second set of phase-shifted clock signals applied to corresponding gates of the second plurality of transistors.

In Example 19, the subject matter of Examples 16-18 includes subject matter where the transmission gate comprises a third plurality of transistors, wherein gate terminals of at least two of the third plurality of transistors are coupled to corresponding gates of at least two of the first plurality of transistors.

Example 20 is a process of making a pulse generator circuit, comprising: coupling a first plurality of transistors and a capacitor in series with each other; coupling the first plurality of transistors between a first supply voltage terminal and a ground terminal; coupling a transmission gate coupled to a second supply voltage terminal; coupling a second plurality of transistors to the transmission gate via the capacitor; and coupling the second plurality of transistors to a data input terminal and an output terminal.

In Example 21, the subject matter of Examples 1-13 includes subject matter where the apparatus is provided in at least one of an integrated circuit, a System on Chip, a System in Package, or a computing device.

Example 22 is at least one machine-readable medium including instructions that, when executed by processing circuitry, cause the processing circuitry to perform operations to implement any of Examples 1-21.

Example 23 is an apparatus comprising means to implement any of Examples 1-21.

Example 24 is a system to implement any of Examples 1-21.

Example 25 is a method to implement any of Examples 1-21.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An apparatus comprising:
a first NMOS transistor comprising a gate terminal coupled to a first clock signal;
a first PMOS transistor comprising a gate terminal coupled to a second clock signal, and a drain terminal of the first NMOS transistor coupled to a source terminal of the first PMOS transistor;
a second NMOS transistor comprising a gate terminal coupled to the second clock signal and the gate terminal of the first PMOS transistor; and
a second PMOS transistor comprising a gate terminal coupled to the gate terminal of the first NMOS transistor.

2. The apparatus of claim 1, further comprising:
a capacitor comprising a first terminal and a second terminal, the first terminal coupled to a source terminal of the first NMOS transistor and a drain terminal of the first PMOS transistor.

3. The apparatus of claim 2, wherein the first terminal of the capacitor is further coupled to a drain terminal of the second NMOS transistor.

4. The apparatus of claim 2, wherein the second terminal of the capacitor is coupled to a drain terminal of the second PMOS transistor.

5. The apparatus of claim 2, further comprising:
a third PMOS transistor comprising a gate terminal coupled to an input data signal and a source terminal coupled to the second terminal of the capacitor.

6. The apparatus of claim 5, further comprising:
a fourth PMOS transistor comprising a source terminal coupled to a drain terminal of the third PMOS transistor and a drain terminal coupled to an output terminal of the pulse generator circuit.

7. The apparatus of claim 6, wherein the fourth PMOS transistor comprises a gate terminal coupled to a third clock signal.

8. The apparatus of claim 6, further comprising:
a third NMOS transistor comprising a drain terminal coupled to the output terminal and a source terminal coupled to a ground terminal.

9. The apparatus of claim 8, wherein the third NMOS transistor comprises a gate terminal coupled to a third clock signal.

10. The apparatus of claim 9, further comprising:
a fourth NMOS transistor comprising a drain terminal coupled to the output terminal, a source terminal coupled to the ground terminal, and a gate terminal coupled to the second clock signal.

11. The apparatus of claim 10, further comprising:
a fifth NMOS transistor comprising a drain terminal coupled to the output terminal, a source terminal coupled to the ground terminal, and a gate terminal coupled to the input data signal.

12. The apparatus of claim 8, wherein the source terminal of the second PMOS transistor is coupled to a first voltage signal generated from a voltage source.

13. The apparatus of claim 12, wherein the drain terminal of the first NMOS transistor and the source terminal of the first PMOS transistor are coupled to a second voltage signal, and wherein the second voltage signal is same as the first voltage signal or is generated from the voltage source.

14. The apparatus of claim 11, comprising a system-on-chip (SoC), the SoC comprising an integrated circuit (IC), the IC comprising at least two transistors of the first PMOS transistor, the second PMOS transistor, the third PMOS transistor, the fourth PMOS transistor, the first NMOS transistor, the second NMOS transistor, the third NMOS transistor, the fourth NMOS transistor, and the fifth NMOS transistor.

15. The apparatus of claim 14, wherein the SoC further comprises at least one connector, and wherein the at least one connector conforms with at least one of Universal Serial Bus (USB), High-Definition Multimedia Interface (HDMI), Thunderbolt, Peripheral Component Interconnect Express (PCIe), Universal Chiplet Interconnect Express (UCIe), high-speed Double Data Rate (DDR) memory interface, and Ethernet specifications.

16. An apparatus comprising:
a capacitor;
a first plurality of transistors coupled in series with each other via the capacitor, and the first plurality of transistors coupled between a first supply voltage terminal and a ground terminal;
a transmission gate coupled to a second supply voltage terminal; and
a second plurality of transistors coupled to the transmission gate via the capacitor, the second plurality of transistors coupled to a data input terminal and an output terminal.

17. The apparatus of claim 16, wherein the first plurality of transistors and the capacitor form a charging path, the charging path to charge the capacitor to a first pre-configured charge based on a first supply voltage at the first supply voltage terminal and a first set of phase-shifted clock signals coupled to corresponding gates of the first plurality of transistors.

18. The apparatus of claim 17, wherein the transmission gate, the capacitor, and the second plurality of transistors form a boosting path, the boosting path to boost the first pre-configured charge of the capacitor to a second pre-configured charge based on a second supply voltage at the second supply voltage terminal and a second set of phase-shifted clock signals applied to corresponding gates of the second plurality of transistors.

19. The apparatus of claim 16, wherein the transmission gate comprises a third plurality of transistors, wherein gate terminals of at least two of the third plurality of transistors are coupled to corresponding gates of at least two of the first plurality of transistors.

20. A process of making a pulse generator circuit, comprising:
coupling a first plurality of transistors and a capacitor in series with each other;
coupling the first plurality of transistors between a first supply voltage terminal and a ground terminal;
coupling a transmission gate coupled to a second supply voltage terminal;
coupling a second plurality of transistors to the transmission gate via the capacitor; and
coupling the second plurality of transistors to a data input terminal and an output terminal.
